(19) United States
(12) Patent Application Publication
(10) Pub. No.: US 2026/0343972 A1
(43) Pub. Date: Oct. 29, 2026

(54) SOURCE/DRAIN EPITAXY PROFILES AND METHODS OF ACHIEVING THE SAME

(71) Applicant: Taiwan Semiconductor Manufacturing Company, Ltd., Hsinchu (TW)

(72) Inventors: Yan-Ting Lin, Baoshan Township (TW); Chien-I Kuo, Zhubei City (TW); Ming-Hua Yu, Hsinchu (TW); Chii-Horng Li, Zhubei City (TW)

(21) Appl. No.: 19/732,909

(22) Filed: Jul. 7, 2026

Related U.S. Application Data
(63) Continuation of application No. 19/080,106, filed on Mar. 14, 2025.
(60) Provisional application No. 63/723,675, filed on Nov. 22, 2024.

(51) Int. Cl. H10D 62/13; H10D 30/00; H10D 30/01; H10D 62/10; H10D 64/23; H10D 84/01; H10D 84/85

(52) U.S. Cl. CPC H10D 62/151; H10D 30/0191; H10D 30/502; H10D 62/121; H10D 64/251; H10D 84/0167; H10D 84/017; H10D 84/851

(57) ABSTRACT

A method includes forming a plurality of semiconductor nanostructures, wherein upper ones of the plurality of semiconductor nanostructures overlap respective lower ones of the plurality of semiconductor nanostructures. The method further includes forming a source/drain recess aside of the plurality of semiconductor nanostructures, and forming a first semiconductor layer from the plurality of semiconductor nanostructures. The first semiconductor layer has a convex shape in a cross-sectional view of the first semiconductor layer. A second semiconductor layer is formed over the first semiconductor layer. A silicide region is formed over and contacting the second semiconductor layer.

### PRIORITY CLAIM AND CROSS-REFERENCE

This application is a continuation of U.S. patent application Ser. No. 19/080,106, filed Mar. 14, 2025, which application claims the benefit of the following provisionally filed U.S. Patent Application No. 63/723,675, filed on Nov. 22, 2024, and entitled “PMOS SOURCE DRAIN EPITAXY FOR DEVICE BOOST ON FFBI NANOSHEET STRUCTURE,” which applications are hereby incorporated herein by reference.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs, and for these advances to be realized, similar developments in IC processing and manufacturing are needed. For example, Gate-All-Around (GAA) Transistors have been introduced to replace planar transistors. The structures of the GAA transistors and methods of fabricating the GAA transistors are being developed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 10A, 10B, 11A, 11B, 12A, 12B, 13A, 13B, 14A, 14B, and 21-23 illustrate the views of intermediate stages in the formation of a Gate All-Around (GAA) transistor in accordance with some embodiments.

FIGS. 15-20 illustrate the views of intermediate stages in the formation of a source/drain region in accordance with alternative embodiments.

FIGS. 24-29 illustrate the views of intermediate stages in the formation of a source/drain region in accordance with alternative embodiments.

FIG. 30 illustrates a process flow for forming a GAA transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Gate All-Around (GAA) transistor and the formation methods are provided. In accordance with some embodiments, the formation of a source/drain region of a GAA transistor includes forming a first epitaxy layer with convex sidewalls, and forming a second epitaxy layer over the first epitaxy layer. The first epitaxy layer has a lower dopant concentration of a dopant (such as boron), and possibly a lower germanium atomic percentage, than the second epitaxy layer. Accordingly, with the first epitaxy layer having convex profiles, the top parts of the epitaxy layer are narrower, yielding more spaces for the second epitaxy layer. The source/drain silicide region and an overlying source/drain contact plug are more likely to land on the second epitaxy layer than on the first epitaxy layer. Accordingly, the source/drain resistance is reduced.

Although GAA transistors are used as an example to discuss the concept of the present disclosure, the embodiments may be applied on other types of transistors including and not limited to planar transistors, Fin Field-Effect Transistors (FinFETs), Complementary Field-Effect Transistors (CFETs), and the like. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

In addition, although a p-type transistor may be discussed as an example in some parts of the discussion, the concept of the present application is readily available for the formation of n-type transistors, with the conductivity types of the corresponding features inversed than in the p-type transistor.

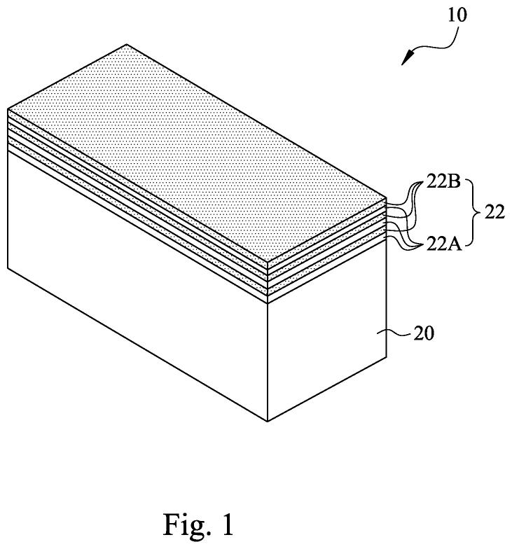

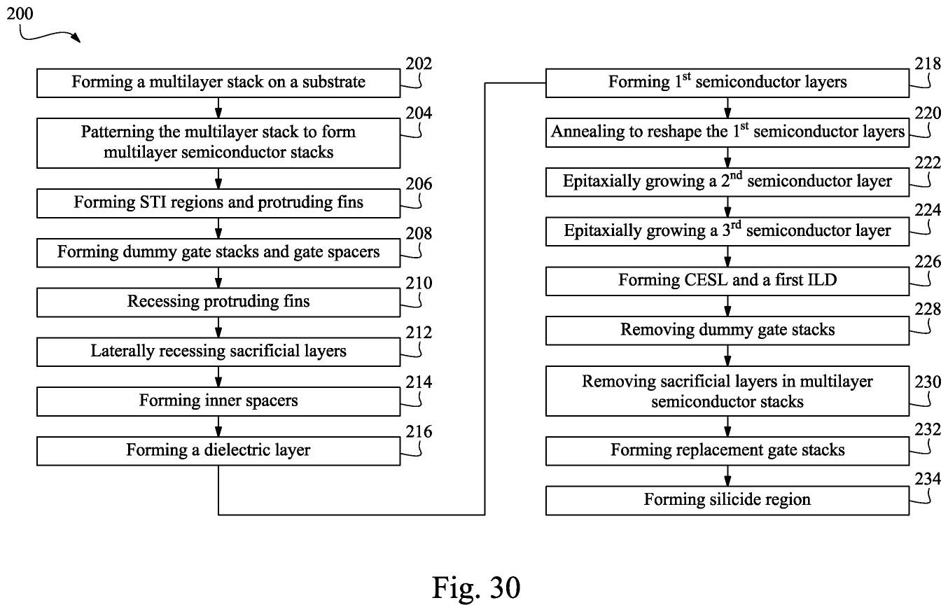

FIGS. 1-4, 5A, 5B, 6A, 6B, 7A, 7B, 8A, 8B, 9A, 9B, 10A, 10B, 11A, 11B, 12A, 12B, 13A, 13B, 14A, 14B, and 15-23 illustrate the cross-sectional views of intermediate stages in the formation of a GAA transistor in accordance with some embodiments of the present disclosure. The corresponding processes are also reflected schematically in the process flow shown in FIG. 30.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor substrate, although in other embodiments, it may be doped as an n-type semiconductor substrate.

In accordance with some embodiments, multilayer stack 22 is formed through a series of deposition processes for depositing alternating materials. The respective process is illustrated as process 202 in the process flow 200 as shown in FIG. 30. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may include Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the first layer 22A has thickness in the range between about 4 nm and 7 nm, while the second layer 22B has thickness in the range between about 8 nm and 12 nm, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask layer(s) (not shown) formed over multilayer stack 22. These layers are patterned, and are used for the subsequent patterning of multilayer stack 22.

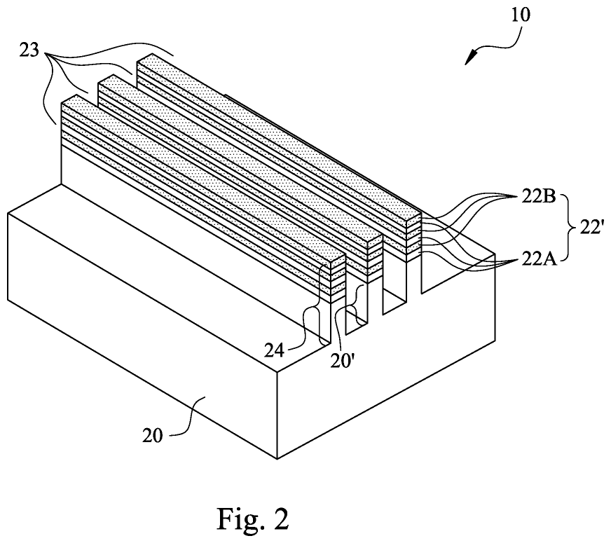

Referring to FIG. 2, multilayer stack 22 and a portion of the underlying substrate 20 are patterned in an etching process(es), so that trenches 23 are formed. The respective process is illustrated as process 204 in the process flow 200 as shown in FIG. 30. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

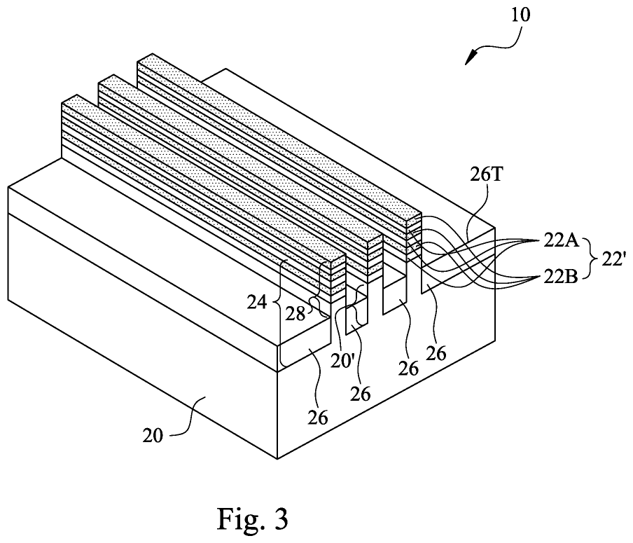

FIG. 3 illustrates the formation of isolation regions 26, which are also referred to as Shallow Trench Isolation (STI) regions throughout the description. The respective process is illustrated as process 206 in the process flow 200 as shown in FIG. 30. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20'. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

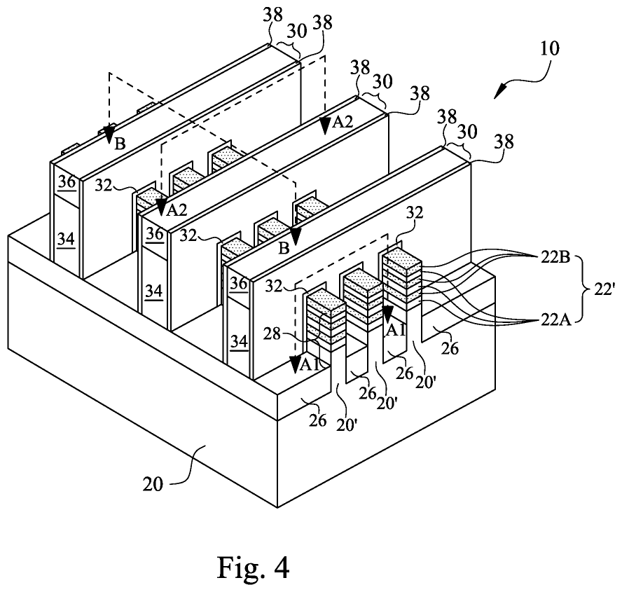

Referring to FIG. 4, dummy gate stacks 30 and gate spacers 38 are formed on the top surfaces and the sidewalls of (protruding) fins 28. The respective process is illustrated as process 208 in the process flow 200 as shown in FIG. 30. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

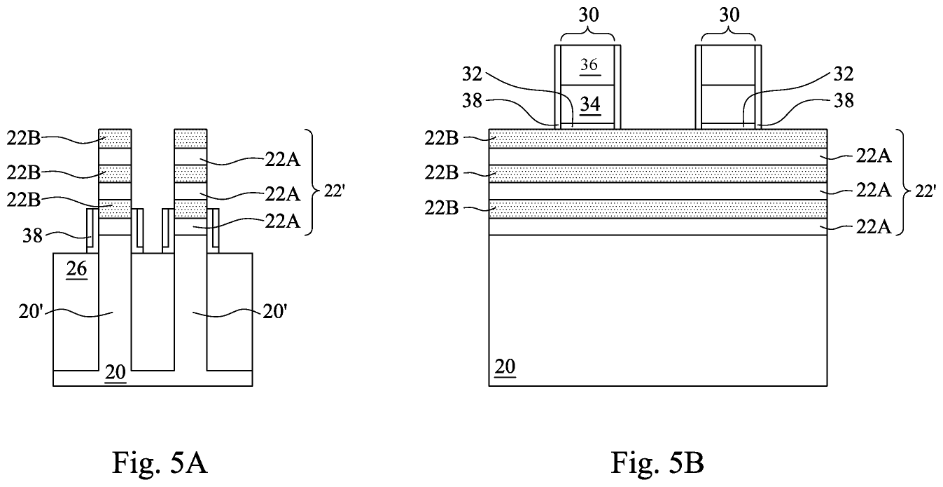

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by dummy gate stacks 30 and gate spacers 38, and is perpendicular to the gate-length direction. FIG. 5B illustrates the reference cross-section B-B in FIG. 4, which reference cross-section is parallel to the lengthwise directions of protruding fins 28.

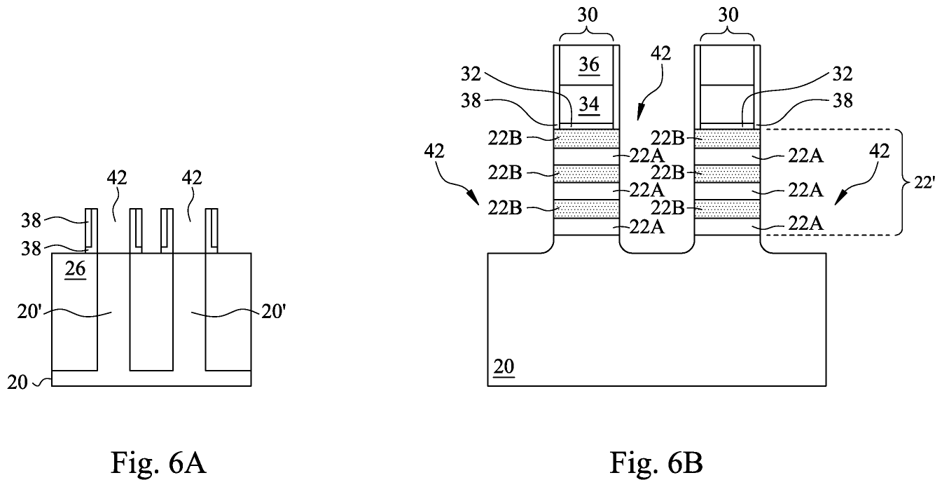

Referring to FIGS. 6A and 6B, the portions of protruding fins 28 (FIG. 4) that are not directly underlying dummy gate stacks 30 and gate spacers 38 are recessed through an etching process to form recesses 42. The respective process is illustrated as process 210 in the process flow 200 as shown in FIG. 30. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20'. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

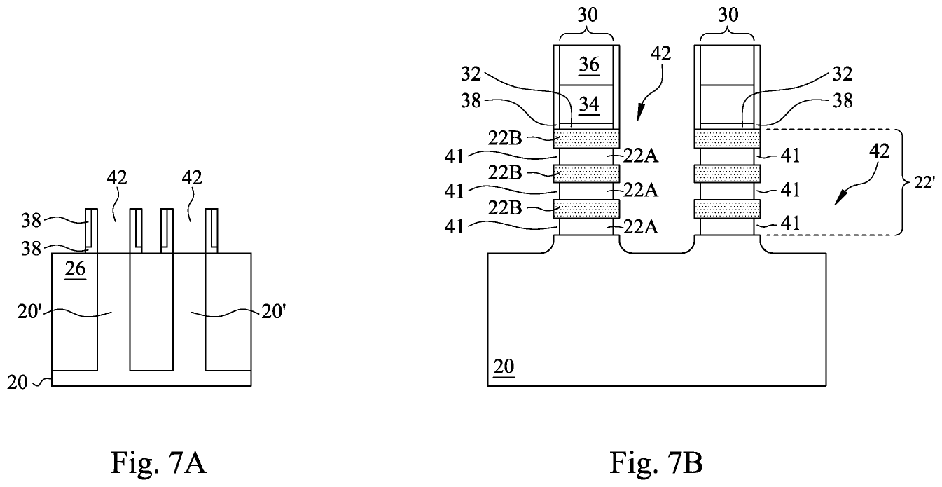

Referring to FIGS. 7A and 7B, sacrificial semiconductor layers 22A are laterally recessed to form lateral recesses 41, which are recessed from the edges of the respective overlying and underlying nanostructures 22B. The respective process is illustrated as process 212 in the process flow 200 as shown in FIG. 30.

The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, a spin-on process, or the like.

In accordance with alternative embodiments, the lateral recessing of sacrificial semiconductor layers 22A is performed through an isotropic dry etching process or a combination of a dry etching process and a wet etching process.

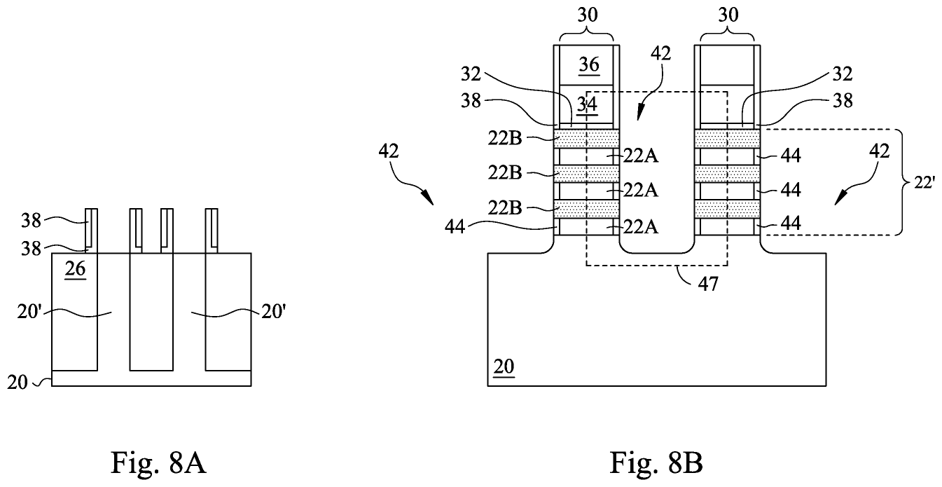

Referring to FIGS. 8A and 8B, inner spacers 44 are formed. The respective process is illustrated as process 214 in the process flow 200 as shown in FIG. 30. In accordance with some embodiments, the formation of inner spacers 44 includes depositing a conformal dielectric layer, which extends into the lateral recesses 41 (FIG. 7B). Next, an etching process (also referred to as a spacer trimming process) is performed to trim the portions of the spacer layer outside of the lateral recesses 41, leaving the portions of the spacer layer in the lateral recesses 41. The remaining portions of the spacer layer are referred to as inner spacers 44. Inner spacers may be single-layer spacers, or may include a plurality of sub layers (such as two to three sub layers).

In accordance with alternative embodiments, inner spacers 44 are not formed, and the subsequently formed source/drain regions may be in contact with the high-k dielectric layers in the replacement gate stacks.

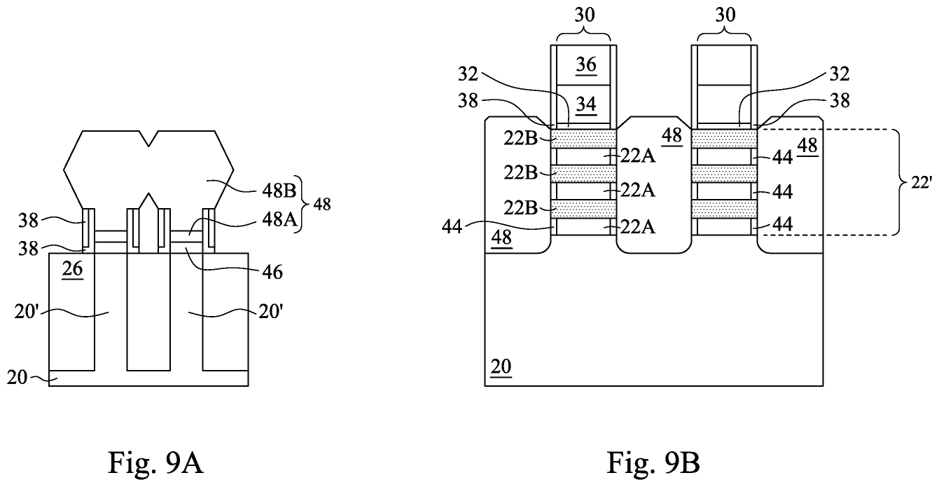

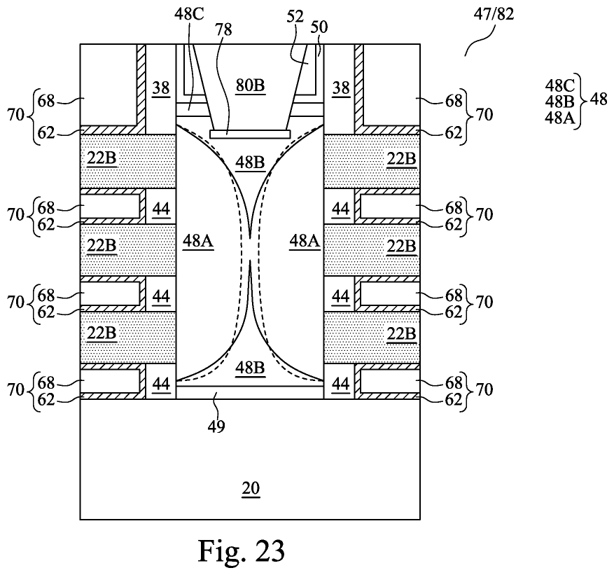

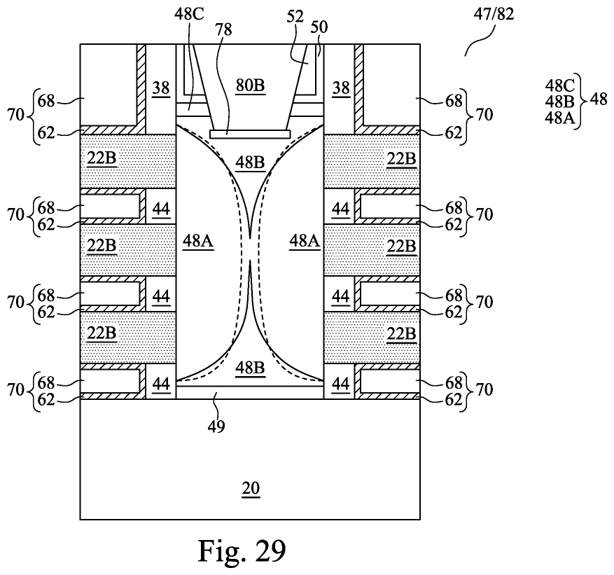

Referring to FIGS. 9A and 9B, source/drain regions 48 are formed in recesses 42, for example, through epitaxy processes. The details of source/drain regions 48 are illustrated in FIG. 23 or 29 in accordance with some embodiments.

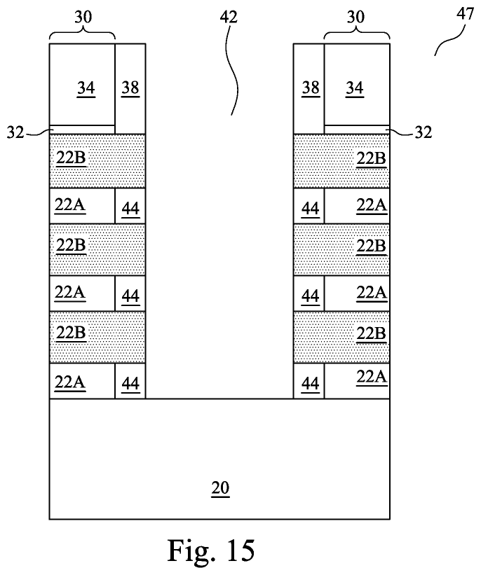

FIGS. 15-20 illustrate the details in the formation of source/drain regions 48 in accordance with some embodiments. FIG. 15 illustrates an amplified view of the region 47 in FIG. 8B, in which recesses 42 and inner spacers 44 have been formed. In the example as shown in FIG. 15, three stacked nanostructures 22B are illustrated as an example. The number of nanostructures 22B in a stack may be any other number, for example, ranging from 2 to about 5.

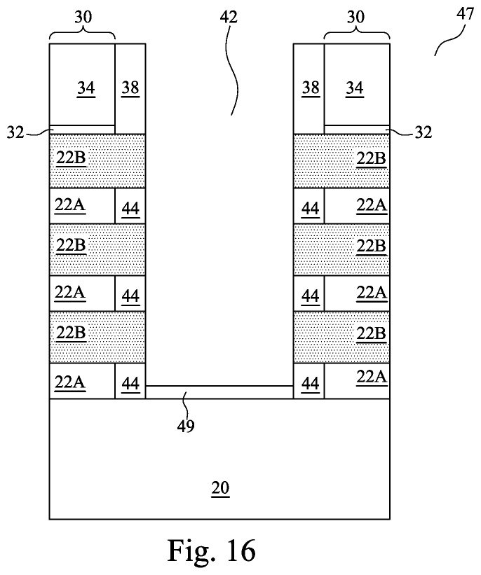

Referring to FIG. 16, dielectric layer 49 is formed at the bottom of recess 42. The respective process is illustrated as process 216 in the process flow 200 as shown in FIG. 30. In accordance with some embodiments, dielectric layer 49 comprises a silicon nitride layer. Dielectric layer 49 may have a single-layer structure including a single layer, or a multilayer structure including a plurality of dielectric layers formed of different dielectric materials. The material of dielectric layer 49 may be selected from silicon oxide, silicon nitride, silicon carbide, silicon oxynitride, or the like, and combinations thereof.

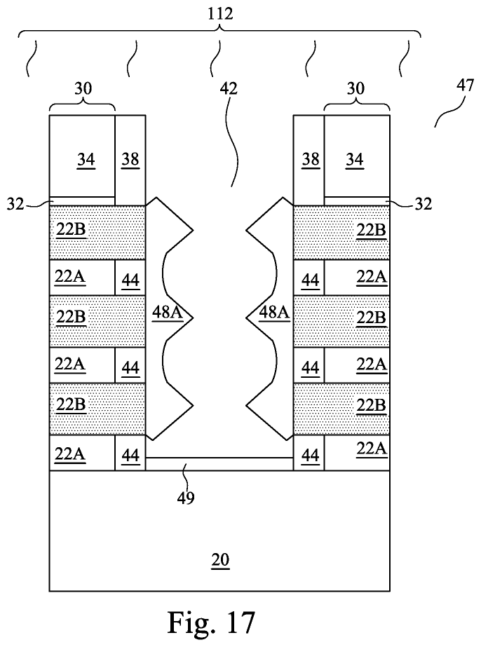

FIG. 17 illustrates the epitaxy of semiconductor layers 48A (also referred to as layer-1 or L1) through a selective epitaxy process. The respective process is illustrated as process 218 in the process flow 200 as shown in FIG. 30. The illustrated semiconductor layers 48A grown from opposite sides of recess 42 are referred to as a first portion and a second portion of a semiconductor layer 48A. The semiconductor layers 48A are selectively grown from the exposed sidewall surfaces of nanostructures 22B. In accordance with some embodiments in which the top surface of semiconductor substrate 20 is on a (100) surface plane, the sidewall surface of the semiconductor layers 48A may be on (110) surface planes. On the other hand, no portion (or a significantly low amount) of semiconductor layers 48A is grown directly starting from the dielectric features such as gate spacers 38 and hard mask 36 (refer to FIG. 9A).

When the source/drain region is a p-type region of a p-type transistor, semiconductor layers 48A may comprise silicon, SiGe, or Ge, and further includes a p-type dopant such as boron, indium, or combinations thereof. For example, semiconductor layers 48A may comprise SiGe, with boron being doped. The semiconductor layers 48A may have a p-type dopant concentration in a range between about 4E20/cm³ and about 7E20/cm³. The gereanium atomic percentage may be in the range between about 0 percent and about 40 percent.

In accordance with alternative embodiments in which the source/drain region is an n-type region of an n-type transistor, semiconductor layers 48A may comprise Si, SiC, or the like and further includes an n-type dopant such as phosphorous, arsenic, antimony, or combinations thereof. For example, semiconductor layers 48A may comprise SiP. The n-type dopant concentration may also be in the range between about 4E20/cm³ and about 7E20/cm³.

In accordance with some embodiments, the formation of semiconductor layers 48A is performed at a first (wafer) temperature, which is relatively low. The first temperature may be in the range between about 400 °C and about 600 °C. During the epitaxy process, a silicon-containing precursor such as silane (SiH₄), di-silane (Si₂H₆), dichlorosilane (DCS, SiH₂Cl₂), or the like, or combinations thereof, may be used as a deposition precursor. An etching gas such as HCl may be added. The flow rate ratio FR_{E}/FR_{D} may be in the range between about 0.2 and about 0.4, wherein value FR_{E} is the flow rate of the etching gas, and value FR_{D} is the flow rate of the deposition precursor that comprises silicon.

In accordance with some embodiments, there may be a plurality of discrete semiconductor layers 48A that are separated from each other, each epitaxially grown from one of nanostructure 22B. The semiconductor layers 48A may have similar (and/or the same) sizes and shapes. Also, the upper ones of the semiconductor layers 48A may have the same sizes, and extend laterally into recess 42 for same or similar distances as the respective lower ones of the semiconductor layers 48A. With the proceeding of the epitaxy process, the portions of the semiconductor layers 48A grown from different nanostructures 22B are merged as integrated pieces, as shown in FIG. 17. The sidewalls of the merged semiconductor layers 48A have an X-shape in a cross-sectional view. Due to the lower growth rate in (111) directions, there may be a plurality of facets formed.

Further referring to FIG. 17, the epitaxy process is stopped, and an annealing process 112 is performed to reshape semiconductor layers 48A. The respective process is illustrated as process 220 in the process flow 200 as shown in FIG. 30. In accordance with some embodiments, the wafer temperature during the annealing process 112 may be in the range between about 700 °C and about 850 °C. The process gas may include inert gases and/or reduction gases that may prevent semiconductor layers 48A from being oxidized. In accordance with some embodiments, the process gases may include hydrogen (H₂), nitrogen (N₂), argon, or combinations thereof. The pressure of the process gas may be in the range between about 20 Torr and about 1 atmosphere. The annealing duration may be in the range between about 30 seconds and about 120 seconds.

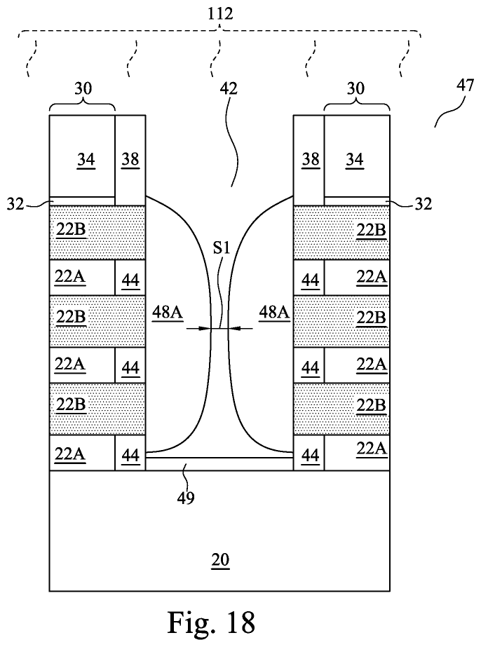

The reshaped semiconductor layers 48A are illustrated in FIG. 18. In the annealing process 112, semiconductor layers 48A are not molten into a liquid. The temperature, however, is high enough, and the annealing duration is long enough to cause the migration of semiconductor layers 48A and to cause the reshaping. As a result, the middle part between the topmost ends and the respective bottommost ends of the semiconductor layers 48A become thicker, and the respective upper parts and lower parts become thinner.

The transition of the thicknesses of different parts of the semiconductor layers 48A at different levels may be continuous. The reduction in thicknesses from the thickest parts to the respective topmost ends and the respective bottom ends may be gradual and continuous. Accordingly, the sidewall surfaces of semiconductor layers 48A may be continuously curved. The thickest parts of semiconductor layers 48A may be at the middle (or close to the middle, for example, with a variation smaller than about 10 percent of the height of semiconductor layers 48A) between the topmost ends and the bottommost ends of the respective semiconductor layers 48A. The resulting semiconductor layers 48A are also referred to as convex semiconductor layers 48A hereinafter. The sidewalls of the semiconductor layers 48A may define a sand timer shaped space in between.

In accordance with some embodiments, the annealing process 112 is ended before the semiconductor layers 48A that are grown from opposing sides of recess 42 are merged, as shown in FIG. 18. In accordance with some embodiments, at the time the annealing process 112 is stopped, the spacing S1 (FIG. 18) between neighboring semiconductor layers 48A may be in the range between about 0 nm and about 13 nm.

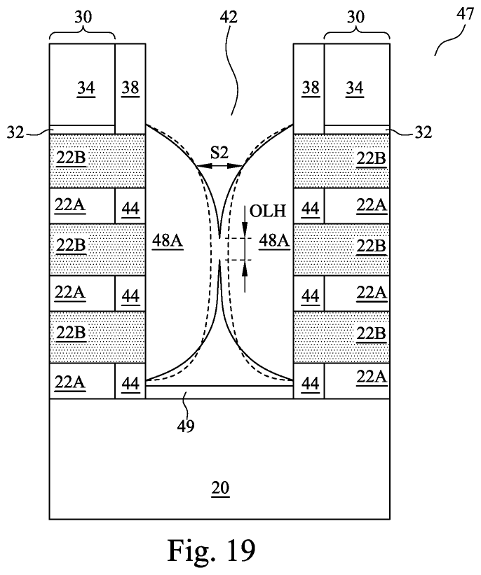

In accordance with alternative embodiments, the annealing process 112 is prolonged. As a result, the top and bottom portions of semiconductor layers 48A become increasingly thinner, and the material of semiconductor layers 48A migrates increasingly to the portion at the middle level. The middle portions of the semiconductor layers 48A grown from opposing sides of the recess 42 are eventually merged. The prolonged annealing process 112 in FIG. 18 is thus shown as being dashed to indicate that the annealing process 112 may be prolonged to cause the merge. The resulting structure is shown in FIG. 19. The sidewalls of the merged semiconductor layers 48A have a X-shape in the cross-sectional view. FIG. 19 further illustrates dashed lines, which represent the sidewalls of semiconductor layers 48A in the embodiments in which semiconductor layers 48A are not to be merged. In accordance with some embodiments, the spacing S2 of the merged semiconductor layers 48A may be in the range between about 5 nm and about 18 nm, wherein spacing S2 is measured at the middle level of the topmost nanostructures 22B. The overlapping height OLH of the merged semiconductor layers 48A may be in the range between about 0 nm and about 20 nm.

In accordance with some embodiments, the formation of the convex semiconductor layers 48A includes a single deposition-and-annealing cycle, which includes a deposition process(es) and a single annealing process 112 for reshaping. In accordance with alternative embodiments, the formation of the convex semiconductor layers 48A includes a plurality of deposition-and-annealing cycles, with each of the deposition-and-annealing cycle including a deposition process followed by an annealing process for reshaping. The very first annealing process 112 is performed after the semiconductor layers 48A grown from the same side of the recesses are all merged into one. Otherwise, the migrated materials will not migrate to the middle level of the respective semiconductor layer 48A. The plurality of deposition-and-annealing cycles may improve the reshaping profile and makes the shapes of semiconductor layers 48A more convex, with the cost of higher manufacturing cost and lower throughput.

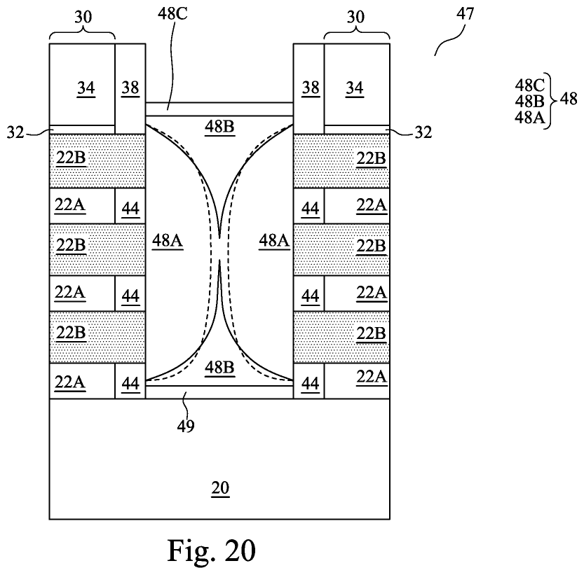

FIG. 20 illustrates the epitaxy growth of semiconductor layer 48B (also referred to as semiconductor layer-2 or L2). The respective process is illustrated as process 222 in the process flow 200 as shown in FIG. 30. The resulting semiconductor layer 48B is grown from, and is different from, semiconductor layers 48A. Semiconductor layer 48B may have a higher p-type dopant concentration than semiconductor layers 48A. For example, when the respective transistor is a p-type transistor, the boron concentration in semiconductor layer 48B may be in a range between about 5E20/cm³ and about 3E21/cm³. When the respective transistor is an n-type transistor, the dopant is an n-type dopant, and the n-type dopant in semiconductor layer 48B may also have a higher dopant concentration than that in semiconductor layers 48A.

It is appreciated that although semiconductor layers 48A may be merged, since the space below the merge point is accessible from the cross-sections different from the illustrated cross-section, semiconductor layer 48B may be filled into the space below the merge point.

In accordance with some embodiments, the formation of semiconductor layer 48B is performed at a second (wafer) temperature, which may be in the same or similar temperature range for forming semiconductor layers 48A, or may be higher than or lower than the first wafer temperature for forming semiconductor layers 48A. For example, the second temperature may be in the range between about 400 °C and about 600 °C.

Semiconductor layer 48B may comprise SiGe with a germanium atomic percentage higher than the germanium atomic percent of semiconductor layers 48A. For example, the germanium atomic percentage in semiconductor layer 48B may be in the range between about 40 percent and about 90 percent. The top surface of semiconductor layer 48B is higher than the topmost ends of semiconductor layers 48A and the topmost surfaces of the topmost nanostructures 22B.

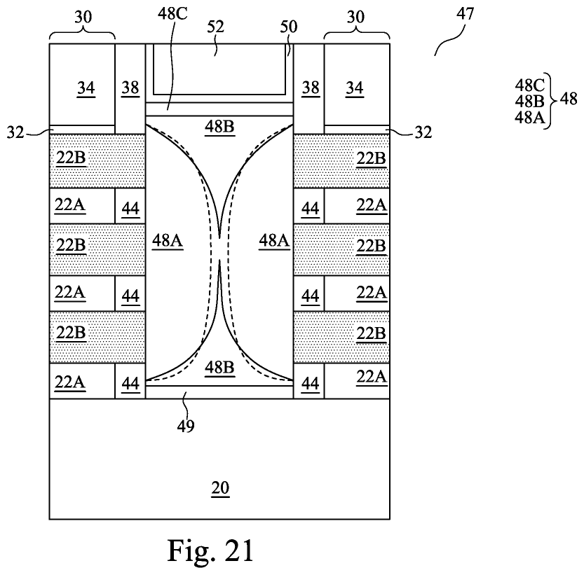

FIG. 21 further illustrates the formation of semiconductor layer (capping layer) 48C in accordance with some embodiments, for example, through a selective epitaxy process. The respective process is illustrated as process 224 in the process flow 200 as shown in FIG. 30. In accordance with some embodiments, capping layer 48C comprises silicon and is free from germanium. Capping layer 48C may also include SiGe with a lower germanium atomic percentage than that in semiconductor layers 48A and 48B. The boron concentration in capping layer 48C may also be lower than or equal to the boron concentration in semiconductor layer 48B. In accordance with alternative embodiments, capping layer 48C is not formed. Throughout the description, semiconductor layers 48A, 48B, and 48C are collectively referred to as source/drain regions 48.

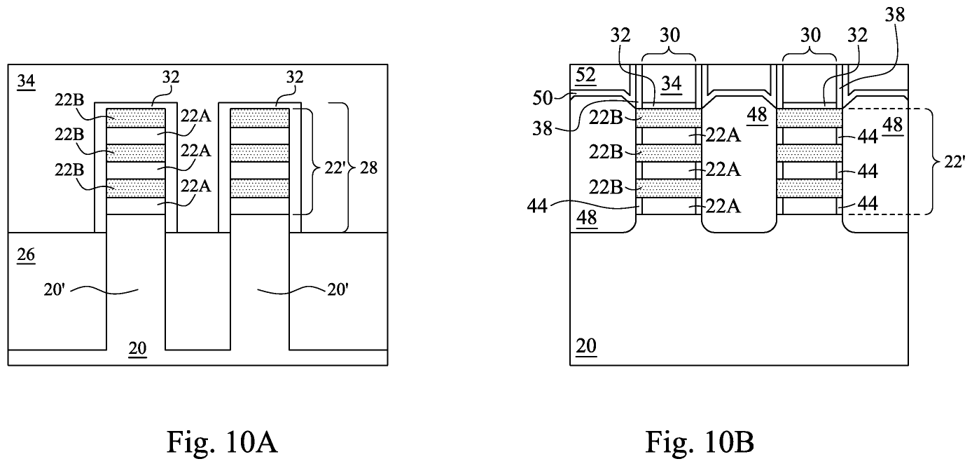

Referring back to FIGS. 10A and 10B, Contact Etch Stop Layer (CESL) 50 and Inter-Layer Dielectric (ILD) 52 are formed. The respective process is illustrated as process 226 in the process flow 200 as shown in FIG. 30. The corresponding structure is also shown in FIG. 21. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be silicon oxide, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. In accordance with some embodiments, the planarization process may remove hard masks 36 to reveal dummy gate electrodes 34, as shown in FIG. 10A. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

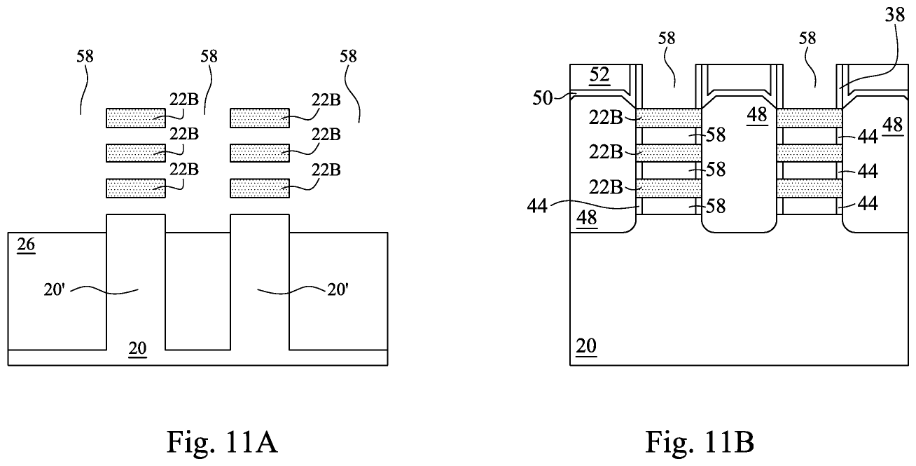

Next, dummy gate electrodes 34 and dummy gate dielectrics 32 (and hard masks 36, if remaining) are removed in one or more etching processes, so that recesses are formed, as shown in FIGS. 11A and 11B. The respective process is illustrated as process 228 in the process flow 200 as shown in FIG. 30.

Sacrificial layers 22A are then removed to extend recesses 58 between nanostructures 22B. The respective process is illustrated as process 230 in the process flow 200 as shown in FIG. 30. Sacrificial layers 22A may be removed by performing an isotropic etching process such as a wet etching process using etchants which are selective to the materials of sacrificial layers 22A, while nanostructures 22B, substrate 20, and STI regions 26 remain relatively un-etched as compared to sacrificial layers 22A.

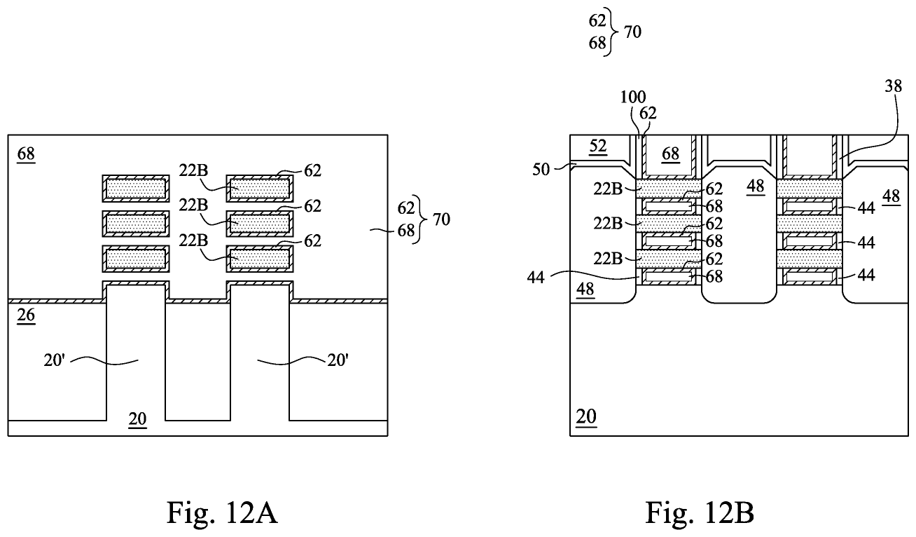

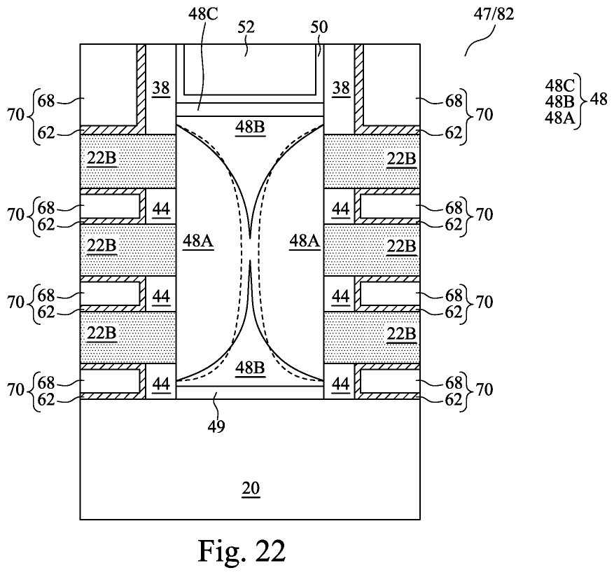

Referring to FIGS. 12A and 12B, gate dielectrics 62 and gate electrodes 68 are formed, hence forming replacement gate stacks 70. The respective process is illustrated as process 232 in the process flow 200 as shown in FIG. 30. The corresponding structure is also shown in FIG. 22. In accordance with some embodiments, each of gate dielectric 62 includes an interfacial layer and a high-k dielectric layer on the interfacial layer. The interfacial layer may be formed of or comprise silicon oxide. In accordance with some embodiments, the high-k dielectric layer comprises one or more dielectric layers. For example, the high-k dielectric layer may include a metal oxide or a silicate of hafnium, aluminum, zirconium, lanthanum, manganese, barium, titanium, lead, and combinations thereof.

Gate electrodes 68 are also formed. In the formation process, conductive layers are first formed on the high-k dielectric layer, and the remaining portions of recesses 58 are filled. Gate electrodes 68 may include a metal-containing material such as TiN, TaN, TiAl, TiAlC, cobalt, ruthenium, aluminum, tungsten, combinations thereof, and/or multilayers thereof.

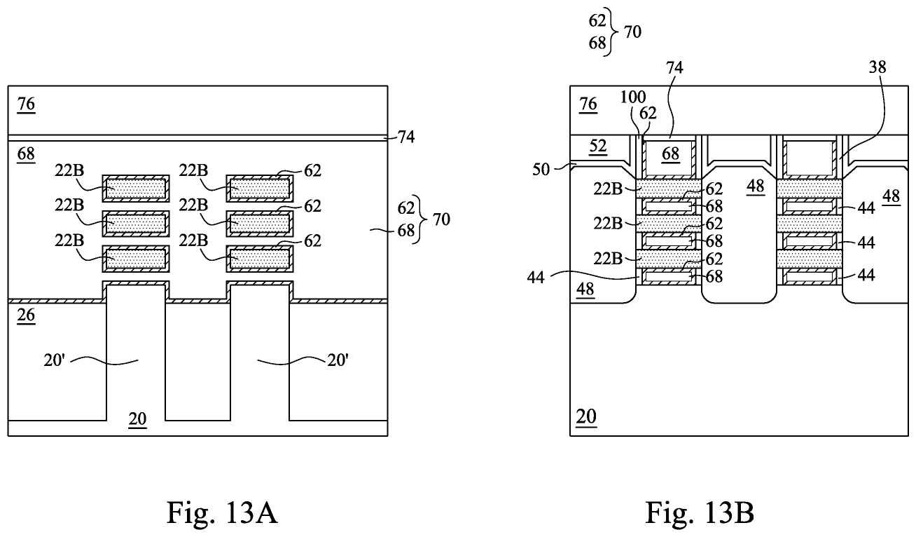

In the processes shown in FIGS. 13A and 13B, gate stacks 70 are recessed, so that recesses are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52.

As further illustrated by FIGS. 13A and 13B, ILD 76 is deposited over ILD 52 and over gate masks 74. An etch stop layer (not shown) may be (or may not be) deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

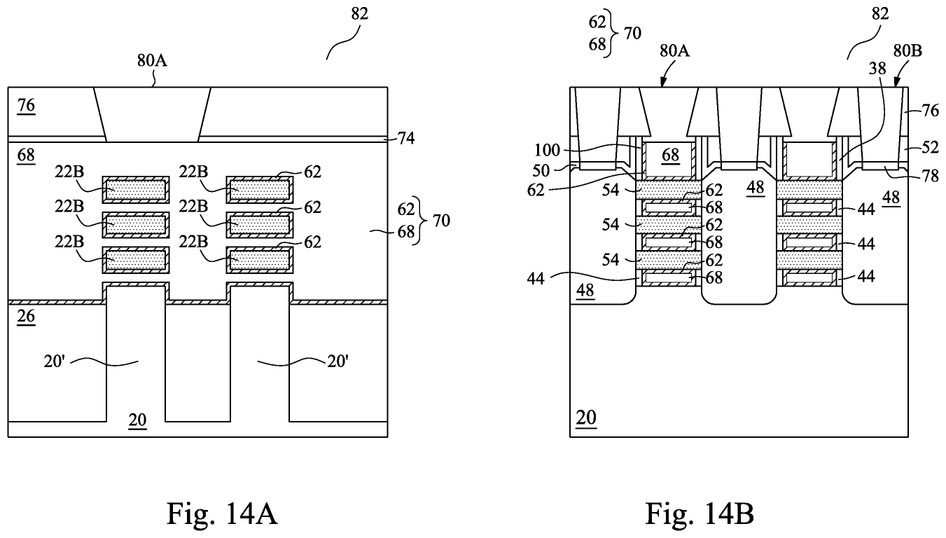

In FIGS. 14A and 14B, ILD 76, ILD 52, CESL 50, and gate masks 74 are etched to form recesses (occupied by contact plugs 80A and 80B) exposing surfaces of source/drain regions 48 and/or gate stacks 70. The recesses may be formed through etching using an anisotropic etching process, such as RIE, NBE, or the like. Although FIG. 14B illustrates that contact plugs 80A and 80B are in a same cross-section, in various embodiments, contact plugs 80A and 80B may be formed in different cross-sections, thereby reducing the risk of shorting with each other.

After the recesses are formed, silicide regions 78 are formed over source/drain regions 48. The respective process is illustrated as process 234 in the process flow 200 as shown in FIG. 30. Contact plugs 80B are then formed over silicide regions 78. Also, contacts 80A (may also be referred to as gate contact plugs) are also formed in the recesses, and are over and contacting gate electrodes 68. The corresponding structure is also shown in FIG. 23. Transistor 82 is thus formed.

FIG. 23 illustrates parts of the transistor 82, which is also shown in FIGS. 14A and 14B. It is appreciated that if the shaping process of semiconductor layers 48A is not performed, some parts of silicide regions 78 and (source/drain) contact plug 80B (also referred to as contact structure 80B) may land on semiconductor layers 48A rather than semiconductor layer 48B. Semiconductor layer 48B may have a higher boron doping concentration and/or a higher germanium atomic percentage than semiconductor layers 48A. Accordingly, by reshaping semiconductor layers 48A and making the top portions of the semiconductor layers 48A smaller, silicide regions 78 are more likely to land on semiconductor layer 48B than on semiconductor layers 48A. The source/drain resistance is thus reduced.

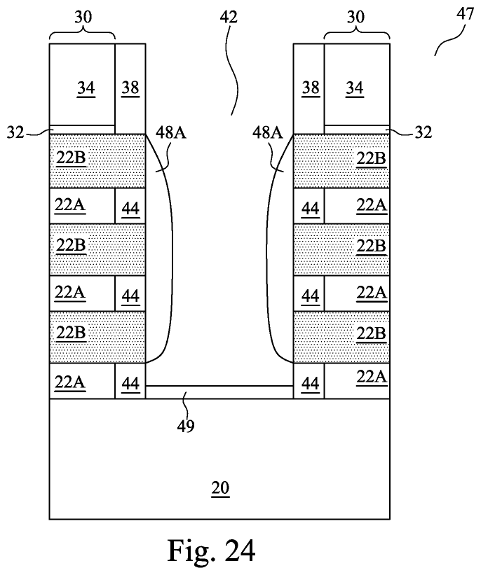

FIGS. 24-29 illustrate the formation of GAA transistor 82 in accordance with alternative embodiments. These embodiments are essentially the same as the preceding embodiments, except that the reshaping of semiconductor layers 48A is performed at the same time (rather than after) semiconductor layers 48A are deposited. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

The initial steps of these embodiments are essentially the same as shown in FIGS. 1-8A/8B. Next, referring to FIG. 24, semiconductor layers 48A are deposited through epitaxy. In accordance with some embodiments, semiconductor layers 48A are deposited as having convex shapes, with the middle parts being thicker than the respective upper parts and the lower parts.

In accordance with some embodiments, the formation of semiconductor layers 48A is performed at a relatively high temperature that may cause the migration of semiconductor layers 48A, and hence semiconductor layers 48A are formed as having convex shapes. The convex shapes also grow with the proceeding of the formation process. The temperature is also higher than the temperature used for forming the semiconductor layers 48A as shown in FIG. 17. In accordance with some embodiments, the temperature for forming the semiconductor layers 48A may be in the range between about 700 °C and about 850 °C.

During the epitaxy process, a silicon-containing precursor such as silane (SiH₄), di-silane (Si₂H₆), dichlorosilane (SiH₂Cl₂), or the like, or combinations thereof, may be used as a deposition precursor. An etching gas such as HCl may be added. To form the convex-shaped semiconductor layers 48A, the flow rate ratio FR_{E}/FR_{D} may also be increased, and may be greater than the flow rate ratio FR_{E}/FR_{D} in the deposition process as shown in FIG. 17. For example, the flow rate ratio FR_{E}/FR_{D} in the process shown in FIG. 24 may be in the range between about 0.4 and about 0.9.

There are other process parameters that may affect the profile of semiconductor layers 48A, which process parameters may include the chamber pressure, deposition rate, or the like, which may also affect the profile of semiconductor layers 48A. By adopting a proper combination of the above-discussed process parameters, convex profile may be achieved for semiconductor layers 48A.

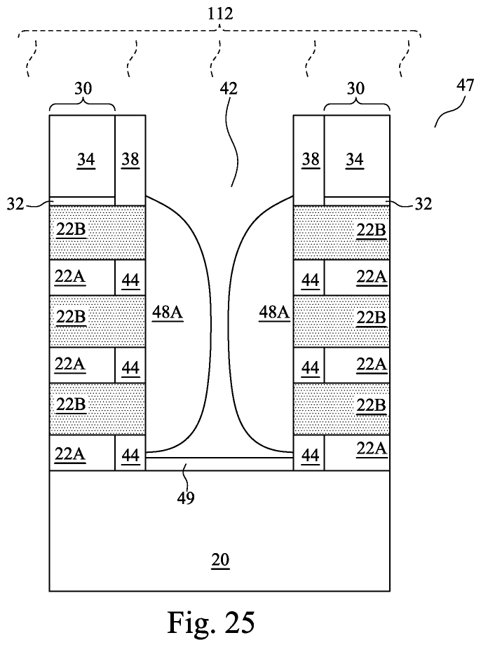

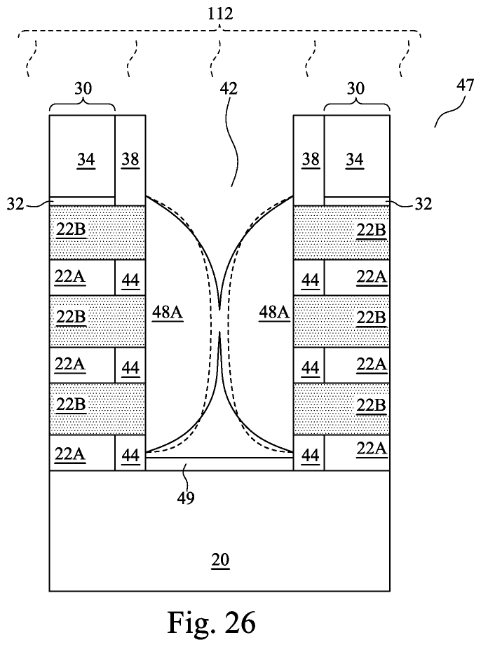

With the proceeding of the epitaxy process, semiconductor layers 48A are grown thicker and larger, as shown in FIG. 25. During the epitaxy process, semiconductor layers 48A keep the convex shape. In accordance with some embodiments, the semiconductor layers 48A may be grown until the opposing portions of semiconductor layers 48A merge with each other, and the resulting structure is shown in FIG. 26. In accordance with alternative embodiments, the formation of semiconductor layers 48A is stopped before merging, as shown in FIG. 25. FIG. 26 illustrates dashed lines to represent the sidewalls of semiconductor layers 48A when they are not to be merged at the time semiconductor layer 48B is formed.

In accordance with some embodiments, as further shown in FIGS. 25 and 26, annealing process 112 may be (or may not be) further performed (when the growth of semiconductor layers 48A is stopped) to reshape semiconductor layers 48A, so that the top portions of semiconductor layers 48A become thinner. There may be a single deposition-and-annealing cycle for growing semiconductor layers 48A, and then performing an annealing process 112 when the precursors for growth are not conducted. Alternatively, there may be a plurality of deposition-and-annealing cycles, with each of the deposition-and-annealing cycles including a deposition process and a subsequent annealing process.

The annealing process 112 may be started either before or after the merging of semiconductor layers 48A. Furthermore, when semiconductor layers 48A are not merged at the time a subsequent annealing process 112 is started, the annealing process 112 may or may not result in the merging of semiconductor layers 48A, as shown by FIGS. 25 and 26. In accordance with alternative embodiments, annealing process 112 is not performed.

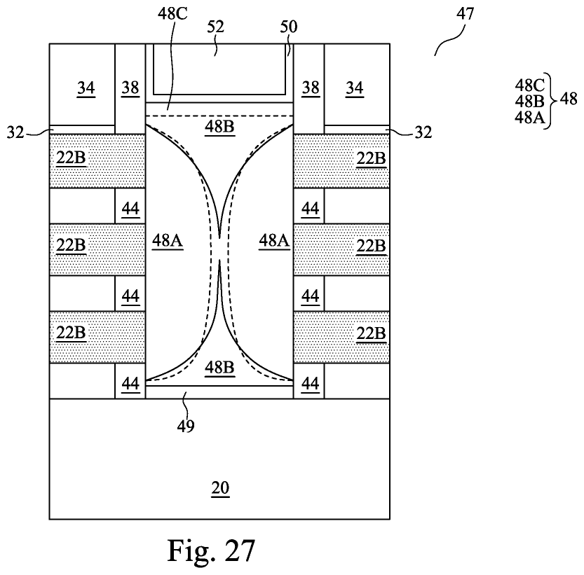

FIG. 27 illustrates the formation of semiconductor layers 48B and 48C in accordance with some embodiments. CESL 50 and ILD 52 are then formed. These processes are essentially the same as discussed referring to FIGS. 20 through 22, and are not repeated herein.

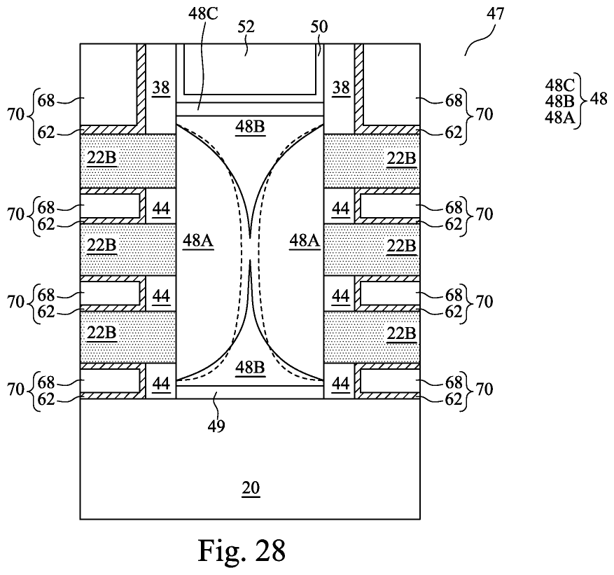

FIG. 28 illustrates the formation of replacement gate stacks 70. FIG. 29 illustrates the formation of silicide region 78 and source/drain contact plug 80B. The processes have been discussed referring to FIG. 23, and are not repeated herein.

The embodiments of the present disclosure have some advantageous features. By forming first semiconductor layers in a source/drain region to have convex cross-sectional view shapes, the top parts of the first semiconductor layers are narrower. The spaces yielded by the narrower top parts are occupied by a second semiconductor layer that has lower resistivity than the first semiconductor layers. The source/drain silicide region is thus more likely to land on the second semiconductor layer. The resistance of the conductive path including the source/drain, the silicide region, and the source/drain contact plug is thus reduced, and the drive current of the transistor is improved. These embodiments have more significant results when dielectric layers are formed under source/drain regions. Due to the dielectric layers that may be formed at the bottom of source/drain regions, smaller strain can be applied to channel regions, and there is an increased need of improving drive current through the reduction of resistance, which need may be achieved by the embodiments of the present disclosure.

In accordance with some embodiments of the present disclosure, a method comprises forming a plurality of semiconductor nanostructures, wherein upper ones of the plurality of semiconductor nanostructures overlap respective lower ones of the plurality of semiconductor nanostructures; forming a source/drain recess aside of the plurality of semiconductor nanostructures; forming a first semiconductor layer from the plurality of semiconductor nanostructures, wherein the first semiconductor layer has a convex shape in a cross-sectional view of the first semiconductor layer; forming a second semiconductor layer over the first semiconductor layer; and forming a silicide region over and contacting the second semiconductor layer.

In an embodiment, the forming the first semiconductor layer comprises: depositing the first semiconductor layer; and performing an annealing process to make a middle portion of the first semiconductor layer thicker. In an embodiment, at a time after the first semiconductor layer is deposited, the first semiconductor layer comprises: a first plurality of portions grown from the plurality of semiconductor nanostructures; and a second plurality of portions between the first plurality of portions, wherein the second plurality of portions are thinner than the first plurality of portions.

In an embodiment, the first semiconductor layer is deposited at a first wafer temperature, and the second semiconductor layer is deposited at a second wafer temperature equal to or higher than the first wafer temperature. In an embodiment, the first semiconductor layer comprises a first portion and a second portion grown toward each other, and wherein at a time the annealing process is finished, the first portion is merged with the second portion.

In an embodiment, the first semiconductor layer comprises a first portion and a second portion grown toward each other, and wherein at a time the annealing process is finished, the first portion is physically separated from the second portion. In an embodiment, at a time the first semiconductor layer is being deposited, a middle portion of the first semiconductor layer is thicker than the respective upper portions and the respective lower portions of the first semiconductor layer.

In an embodiment, the first semiconductor layer is deposited at a first wafer temperature, and the second semiconductor layer is deposited at a second wafer temperature lower than the first wafer temperature. In an embodiment, the method further comprises, before the first semiconductor layer is formed, forming a dielectric layer at a bottom of the source/drain recess. In an embodiment, the first semiconductor layer is spaced apart from the dielectric layer by the second semiconductor layer. In an embodiment, the second semiconductor layer has a higher boron concentration than the first semiconductor layer.

In accordance with some embodiments of the present disclosure, a method comprises forming a semiconductor stack comprising a plurality of semiconductor nanostructures; and forming a source/drain region comprising: epitaxially growing a first semiconductor layer comprising a first portion and a second portion at a same level, wherein the first portion and the second portion are grown toward each other, and wherein the first portion comprises a bottom portion, a top portion, and a middle portion between the bottom portion and the top portion; annealing the first semiconductor layer, wherein a first thickness of the middle portion is increased, and second thicknesses of the top portion and the bottom portion are reduced; and epitaxially growing a second semiconductor layer over the first semiconductor layer.

In an embodiment, after the first semiconductor layer is annealed, the first portion is spaced apart from the second portion. In an embodiment, before the first semiconductor layer is annealed, the first portion has a non-convex profile, and after the first semiconductor layer is merged, the first semiconductor layer has an X-shaped sidewall. In an embodiment, the first portion and the second portion of the first semiconductor layer have convex profiles at both of a first time before the first semiconductor layer is annealed and a second time after the first semiconductor layer is annealed. In an embodiment, the first semiconductor layer is deposited at a first temperature, and the second semiconductor layer is deposited at a second temperature lower than the first temperature.

In accordance with some embodiments of the present disclosure, a structure comprises a semiconductor stack comprising a plurality of semiconductor nanostructures, wherein the plurality of semiconductor nanostructures comprise: a first semiconductor nanostructure; and a second semiconductor nanostructure overlapped by the first semiconductor nanostructure; a source/drain region aside of the semiconductor stack, the source/drain region comprising: a first semiconductor layer comprising a first portion and a second portion, wherein the first portion comprises a middle portion having a greatest thickness of the first portion, and wherein thicknesses of the first portion reduce gradually toward respective upper parts and lower parts of the first portion; and a second semiconductor layer between the first portion and the second portion of the first semiconductor layer; a source/drain silicide region over and contacting the second semiconductor layer, wherein the source/drain silicide region is spaced apart from the first semiconductor layer; and a source/drain contact plug over and contacting the source/drain silicide region.

In an embodiment, the first portion is joined to the second portion, and wherein in a cross-sectional view of the structure, a first sidewall of the first portion is joined to a second sidewall of the second portion to form a X-shape. In an embodiment, the first portion is spaced apart from the second portion, and a part of the second semiconductor layer between the first portion and the second portion has a sand timer shape in a cross-sectional view of the structure. In an embodiment, the structure further comprises a dielectric layer under the first semiconductor layer and the second semiconductor layer, wherein the first semiconductor layer is spaced apart from the dielectric layer by a bottom portion of the second semiconductor layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a plurality of semiconductor nanostructures, wherein upper ones of the plurality of semiconductor nanostructures overlap respective lower ones of the plurality of semiconductor nanostructures;
forming a source/drain recess on a side of the plurality of semiconductor nanostructures;
forming a first semiconductor layer starting from the plurality of semiconductor nanostructures;
performing an annealing process to modify a shape of the first semiconductor layer;
forming a second semiconductor layer over the first semiconductor layer; and
forming a silicide region over the second semiconductor layer.

2. The method of claim 1, wherein before the annealing process, the first semiconductor layer comprises concave sidewalls, and after the annealing process, the first semiconductor layer has a convex sidewall extending from a topmost end to a bottommost end of the first semiconductor layer.

3. The method of claim 2, wherein at a time before the annealing process is performed, the first semiconductor layer comprises:
a first plurality of portions grown from the plurality of semiconductor nanostructures; and
a second plurality of portions between the first plurality of portions, wherein the second plurality of portions are thinner than the first plurality of portions.

4. The method of claim 1, wherein the first semiconductor layer comprises a thickest portion close to a middle height of the plurality of semiconductor nanostructures, and wherein from the thickest portion to a top end of the first semiconductor layer, thicknesses of the first semiconductor layer reduce gradually.

5. The method of claim 1, wherein the first semiconductor layer is deposited at a first wafer temperature, and the second semiconductor layer is deposited at a second wafer temperature equal to or higher than the first wafer temperature.

6. The method of claim 1, wherein the first semiconductor layer comprises a first portion and a second portion grown toward each other from opposite sides of the source/drain recess, and wherein at a time the annealing process is finished, the first portion is merged with the second portion.

7. The method of claim 1, wherein the first semiconductor layer comprises a first portion and a second portion grown toward each other from opposite sides of the source/drain recess, and wherein at a time the annealing process is finished, the first portion is physically separated from the second portion.

8. The method of claim 1 further comprising, before the first semiconductor layer is formed, forming a dielectric layer at a bottom of the source/drain recess.

9. The method of claim 8, wherein the first semiconductor layer is spaced apart from the dielectric layer by the second semiconductor layer.

10. The method of claim 1, wherein the second semiconductor layer has a higher germanium atomic percentage than the first semiconductor layer.

11. A method comprising:
forming a semiconductor stack comprising a plurality of semiconductor nanostructures;
etching the semiconductor stack to form a source/drain recess;
forming a source/drain region in the source/drain recess, wherein the source/drain region is formed by processes comprising:
epitaxially growing a first semiconductor layer comprising a first portion and a second portion at a same level, wherein the first portion and the second portion are on opposite sides of a vertical middle line of the source/drain recess;
after the first semiconductor layer is grown, reshaping the first portion and the second portion the first semiconductor layer to modify a shape of the first portion and the second portion; and
epitaxially growing a second semiconductor layer over the first semiconductor layer, wherein the second semiconductor layer is grown to a level higher than a topmost semiconductor nanostructure of the plurality of semiconductor nanostructures.

12. The method of claim 11, wherein the reshaping the first semiconductor layer comprises an annealing process, and wherein the anneal process results in the first semiconductor layer to migrate.

13. The method of claim 12, wherein the annealing process is performed at a wafer temperature lower than a melting temperature of the first semiconductor layer.

14. The method of claim 12, wherein during the annealing process, a first thickness of a middle portion of the first semiconductor layer is increased, and second thicknesses of upper portions and lower portions of the first semiconductor layer are reduced, and wherein the upper portions are higher than the middle portion, and the lower portions are lower than the middle portion.

15. The method of claim 11, wherein the first semiconductor layer is deposited at a first wafer temperature, and the second semiconductor layer is deposited at a second wafer temperature lower than the first wafer temperature.

16. The method of claim 11, wherein after the first semiconductor layer is reshaped, the first semiconductor layer comprises sidewalls that form an X-shape.

17. A method comprising:
forming a semiconductor stack comprising a plurality of semiconductor nanostructures, wherein the semiconductor stack has a middle semiconductor nanostructure;
etching the semiconductor stack to form a source/drain recess; and
forming a source/drain region in the source/drain recess, wherein the source/drain region is formed by processes comprising:
forming a first semiconductor layer comprising a plurality of parts joined to the plurality of semiconductor nanostructures, wherein the plurality of parts are joined together to form a continuous semiconductor region, and a thickness of the first semiconductor layer measured at a level close to the middle semiconductor nanostructure is a greatest thickness of the first semiconductor layer; and
epitaxially growing a second semiconductor layer to fill the source/drain recess.

18. The method of claim 17 further comprising:
forming a source/drain silicide region over and contacting the second semiconductor layer, wherein the source/drain silicide region is spaced apart from the first semiconductor layer.

19. The method of claim 17, wherein the forming the first semiconductor layer comprises:
performing an epitaxial growth to deposit the first semiconductor layer; and
performing an annealing process to modify a shape of the first semiconductor layer.

20. The method of claim 19, wherein before the annealing process, a thickest part of the first semiconductor layer is at an addition level that is further away from the middle semiconductor nanostructure than after the annealing process.
